(19) United States
(12) Patent Application Publication
(10) Pub. No.: US 2026/0372083 A1
(43) Pub. Date: Nov. 19, 2026

(54) FLIPPED SUBMODULES ON LAMINATE FOR ENHANCED THERMAL MANAGEMENT

(71) Applicant: Qorvo US, Inc., Greensboro, NC (US)

(72) Inventors: Vladimir Kolchuzhin, Hohenschaeftlarn (DE); Andriy Kryshtopin, Kirchseeon (DE); Asdesach Zena Markos, Munich (DE)

(21) Appl. No.: 19/674,800

(22) Filed: May 12, 2026

Related U.S. Application Data
(60) Provisional application No. 63/808,197, filed on May 19, 2025.

(51) Int. Cl. H10W 40/20; H03H 9/00; H03H 9/64; H04B 1/40; H04L 25/02; H10W 40/00; H10W 42/20; H10W 44/20; H10W 72/00; H10W 90/00; H10W 90/10; H10W 90/22

(52) U.S. Cl. CPC H10W 40/242; H03H 9/0009; H03H 9/0014; H03H 9/64; H04B 1/40; H04L 25/02; H10W 40/03; H10W 42/273; H10W 42/276; H10W 44/203; H10W 72/877; H10W 90/10; H10W 90/22; H10W 90/401; H10W 90/724; H10W 90/7295; H10W 90/734

(57) ABSTRACT

The present disclosure relates to a radio frequency (RF) system-in-package (SIP) module for enhanced thermal management, which includes a module substrate and a flipped submodule having a submodule substrate, submodule flip-chip dies, and submodule interconnects. Herein, each submodule flip-chip die is attached to a first side of the submodule substrate, and a backside of each submodule flip-chip die is thermally connected to a top side of the module substrate via a thermal interface material for heat dissipation. Each submodule interconnect extends from the first side of the submodule substrate towards the top side of the module substrate and is configured to provide electrical and thermal connections between the submodule substrate and the module substrate. The submodule substrate includes multiple metal layers, which are configured to provide passive components and achieve electrical and thermal connections among the passive components, the submodule flip-chip dies, and the submodule interconnects.

### RELATED APPLICATIONS

This application claims the benefit of provisional patent application Ser. No. 63/808,197, filed May 19, 2025, the disclosure of which is hereby incorporated herein by reference in its entirety.

### FIELD OF THE DISCLOSURE

The present disclosure relates to a radio frequency (RF) system-in-package (SIP) module with one or more flipped submodules for enhanced thermal management, and a process of manufacturing the RF SIP module including the one or more flipped submodules.

### BACKGROUND

The trends in mobile device electronics, particularly in radio frequency (RF) front-end (FE) modules, are driven by the demand for increased functionality in smaller form factors. These trends have been further intensified with the introduction of 5th Generation (5G) technology. To support the extensive carrier aggregations and bandwidth enhancements required for 5G, these modules now incorporate a greater number of acoustic filters, such as bulk acoustic wave (BAW) filters or surface acoustic wave (SAW) filters, connected in intricate multiplexer networks. These networks are further complemented by switches, power amplifiers (PAs), and low-noise amplifiers (LNAs).

Concurrently, there is an increasing trend toward more frequent use of power class 2 (PC2, 29-30 dBm) operation. For example, 3rd Generation Partnership Project (3GPP) requirements specify PC2 operation for certain frequency division duplex (FDD) bands. Some proposed applications, such as non-terrestrial networks (NTN), contemplate power class 1.5 (PC1.5, 31-32 dBm) operation. Although power class 3 (PC3, 27 dBm) operation is expected to remain available, the increased adoption of PC2 and higher power levels results in greater power transmission through RF front-end components. The continuing push toward greater integration, miniaturization, and higher power handling capability, while maintaining low manufacturing cost, increasingly approaches the physical limits of semiconductor processing, packaging, and manufacturing technologies, and further presents substantial technological challenges in RF packaging integration.

On the other hand, due to filter insertion loss (IL), a significant portion of input power is converted into undesired heat. This effect will cause an increase in temperature of the filter device (e.g., a transmitter filter in the RF FE module), thereby causing a downshift of its frequency characteristic. If the frequency characteristic goes down, the filter loss at the upper band edge (UBE) goes up, which leads to a further rise in temperature of the filter device. Therefore, at some point, the filter device might be destroyed, or a desired output power might not be achieved.

Accordingly, to accommodate increased integration levels and miniaturization of an RF SIP module, and to enhance thermal management of filter devices within the RF SIP module, it is therefore an object of the present disclosure to provide an improved design of the RF SIP module and a process for making the same.

### SUMMARY

The present disclosure relates to a radio frequency (RF) system-in-package (SIP) module with one or more flipped submodules for enhanced thermal management, and a process of manufacturing the RF SIP module including the one or more flipped submodules. According to one embodiment, the disclosed RF SIP module includes a module substrate, a flipped submodule attached to a top side of the module substrate, and at least one top component attached to the top side of the module substrate. Herein, the flipped submodule has a submodule substrate, at least one submodule component, and a number of submodule interconnects. The at least one submodule component is a flip-chip die attached to a first side of the submodule substrate that faces the top side of the module substrate. A backside of the at least one submodule component is thermally connected to the top side of the module substrate via a thermal interface material, which allows heat generated by the at least one submodule component to dissipate from the backside of the at least one submodule component towards the module substrate. Each of the submodule interconnects extends from the first side of the submodule substrate towards the top side of the module substrate and is configured to provide electrical and thermal connections between the submodule substrate and the module substrate. The submodule substrate includes a number of metal layers, which is configured to provide at least one passive component and achieve electrical and thermal connections among the at least one passive component, the at least one submodule component, and the submodule interconnects.

In one embodiment of the RF SIP module, the thermal interface material has a thermal conductivity larger than 3 W/mK and a thickness between 20 μm and 30 μm.

In one embodiment of the RF SIP module, the submodule substrate includes 3 to 5 metal layers.

In one embodiment of the RF SIP module, the at least one submodule component includes one or more acoustic filters, and the at least one passive component includes one or more corresponding ground coils.

In one embodiment of the RF SIP module, the at least one submodule component includes two or more acoustic filters, and the metal layers within the submodule substrate are configured to provide one or more corresponding ground coils for each of the two or more acoustic filters.

In one embodiment of the RF SIP module, the metal layers within the submodule substrate are further configured to provide a multiplexing network connected to the two or more acoustic filters, thereby forming a multiplexer, such that the two or more acoustic filters of the multiplexer are capable of being individually selected by an antenna switch to operate.

In one embodiment of the RF SIP module, the two or more acoustic filters are bulk acoustic wave (BAW) filters or surface acoustic wave (SAW) filters.

In one embodiment of the RF SIP module, the at least one passive component comprises at least one of a coil, a capacitor, a resistor, and a transformer.

In one embodiment of the RF SIP module, each of the submodule interconnects is a copper pillar, a solder ball, or a wire-bond.

In one embodiment of the RF SIP module, the module substrate includes a top metal layer that has a number of top metal features and is formed on the top side of the module substrate. The thermal interface material is directly and vertically positioned between the backside of the at least one submodule component and a corresponding one of the top metal features on the top side of the module substrate. Each of the submodule interconnects is electrically connected to another corresponding one of the top metal features on the top side of the module substrate.

In one embodiment of the RF SIP module, the flipped submodule further includes a submodule mold compound, which is formed vertically between the first side of the submodule substrate and the top side of the module substrate, surrounds the at least one submodule component and each of the submodule interconnects, and underfills the at least one submodule component.

According to one embodiment, the RF SIP module further includes a top mold compound, which is formed on the top side of the module substrate to fully encapsulate the at least one top component and the flipped submodule.

In one embodiment of the RF SIP module, the top mold compound and the submodule mold compound are formed from different materials.

According to one embodiment, the RF SIP module further includes a module shielding structure, which directly and continuously covers a top surface of the top mold compound and a combined side surface of the top mold compound and the module substrate.

According to one embodiment, the RF SIP module further includes one or more internal shielding structures, each of which is connected to a corresponding one of the top metal features on the top side of the module substrate, extends vertically through the top mold compound, and is in contact with the module shielding structure.

According to one embodiment, the RF SIP module further includes at least one bottom component and a number of bump structures. Herein, the at least one bottom component and the bump structures are attached to a bottom side of the module substrate, which is opposite from the top side of the module substrate.

According to one embodiment, the RF SIP module further includes a bottom mold compound, which surrounds each of the bump structures without covering an end surface of each of the bump structures. The bottom mold compound at least surrounds the at least one bottom component, and the at least one bottom component does not vertically extend beyond the bottom mold compound.

According to one embodiment, a communication device includes a control system, a baseband processor, receive circuitry, and transmit circuitry. Herein, at least one or any combination of the control system, the baseband processer, the transmit circuitry, and the receive circuitry is implemented in an RF SIP module, which includes a module substrate, a flipped submodule, and at least one top component. The at least one top component and the flipped submodule, which includes a submodule substrate, at least one submodule component, and a number of submodule interconnects, are attached to a top side of the module substrate. The at least one submodule component is a flip-chip die attached to a first side of the submodule substrate that faces the top side of the module substrate. A backside of the at least one submodule component is thermally connected to the top side of the module substrate via a thermal interface material, which allows heat generated by the at least one submodule component to dissipate from the backside of the at least one submodule component towards the module substrate. Each of the submodule interconnects extends from the first side of the submodule substrate towards the top side of the module substrate and is configured to provide electrical and thermal connections between the submodule substrate and the module substrate. The submodule substrate includes a number of metal layers, which is configured to provide at least one passive component and achieve electrical and thermal connections among the at least one passive component, the at least one submodule component, and the submodule interconnects.

According to one embodiment, a method of fabricating an RF SIP module starts with forming a flipped submodule, which includes a submodule substrate, at least one submodule component, and a number of submodule interconnects. Herein, the at least one submodule component is a flip-chip die attached to a first side of the submodule substrate, such that a backside of the at least one submodule component is away from the first side of the submodule substrate. Each of the submodule interconnects is formed on the first side of the submodule substrate. The submodule substrate includes a number of metal layers, which is configured to provide at least one passive component and achieve electrical and thermal connections among the at least one passive component, the at least one submodule component, and the submodule interconnects. A thermal interface material is then deposited on a top side of a module substrate. Next, the flipped submodule and at least one top component are attached to the top side of the module substrate. The backside of the at least one submodule component is thermally connected to the module substrate via the thermal interface material, which allows heat generated by the at least one submodule component to dissipate from the backside of the at least one submodule component towards the module substrate. Each of the submodule interconnects extends from the first side of the submodule substrate towards the top side of the module substrate and is configured to provide electrical and thermal connections between the submodule substrate and the module substrate.

In one embodiment of the method, the thermal interface material has a thermal conductivity larger than 3 W/mK and a thickness between 20 μm and 30 μm.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary system-in-package (SIP) module with a flipped submodule according to some embodiments of the present disclosure.

FIGS. 2A and 2B illustrate three-dimensional 3D plots for different RF SIP modules.

FIG. 3 provides a flow diagram that illustrates an exemplary process for manufacturing the flipped submodule according to some embodiments of the present disclosure.

FIG. 4 provides a flow diagram that illustrates an exemplary process for manufacturing the RF SIP module according to some embodiments of the present disclosure.

FIG. 5 is a block diagram of a communication device, which may include the RF SIP module according to some embodiments of the present disclosure.

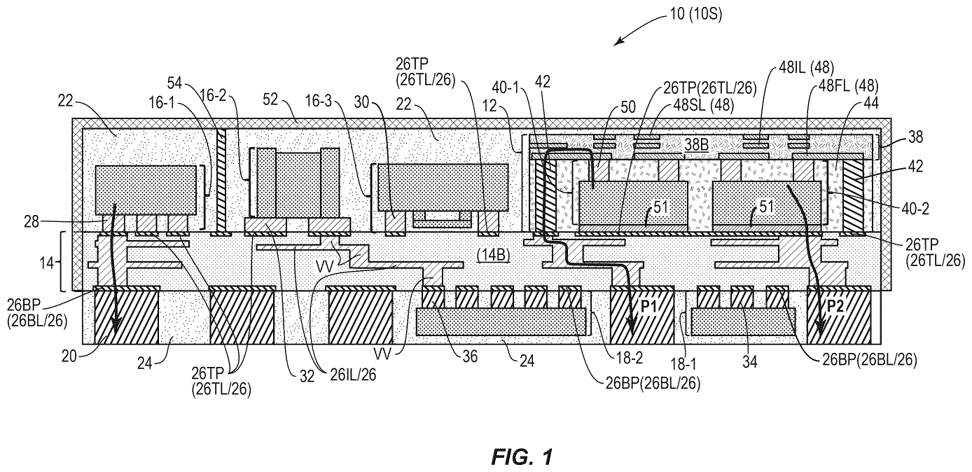

It will be understood that for clarity of illustration, FIGS. 1-5 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a radio frequency (RF) system-in-package (SIP) module with one or more flipped submodules for enhanced thermal management and a process of manufacturing the RF SIP module including the one or more flipped submodules. In particular, the RF SIP module utilizes the flipped submodules to improve heat dissipation for electronic components with temperature-sensitive characteristics, such as acoustic filters.

FIG. 1 illustrates an exemplary RF SIP module 10 with a flipped submodule 12 according to some embodiments of the present disclosure. For the purpose of this illustration, besides the flipped submodule 12, the RF SIP module 10 also includes a module substrate 14, three top components 16 (e.g., a first top component 16-1, a second top component 16-2, and a third top component 16-3), two bottom components 18 (e.g., a first bottom component 18-1 and a second bottom component 18-2), multiple bump structures 20 (for clarity and simplicity, only one bump structure is labeled with a reference number), a top mold compound 22, and a bottom mold compound 24. Herein, the flipped submodule 12 and the top components 16 are formed on a top side of the module substrate 14, and the top components 16 are located at one horizontal side of the flipped submodule 12. The bottom components 18 and the bump structures 20 are placed on a bottom side of the module substrate 14. The bump structures 20 serve as input/outputs (I/Os) of the RF SIP module, which may surround each bottom component 18 and separate the bottom components 18 from each other. The top mold compound 22 is formed on the top side of the module substrate 14 to fully encapsulate the flipped submodule 12 and each top component 16. The bottom mold compound 24 is formed on the bottom side of the module substrate 14 to fully encapsulate each bottom component 18 and substantially cover sides of each bump structure 20. As such, an end surface of each bump structure 20 is exposed through the bottom mold compound 24. The top mold compound 22 and the bottom mold compound 24 may be formed of a same or different molding material.

In different applications, the RF SIP module 10 may include more flipped submodules 12, fewer or more top components 16 of various types (e.g., surface mounted devices, flip-chip dies, wire-bonding dies, passive electronic components, etc.), fewer or more bottom components 18 of various types (e.g., surface mounted devices, flip-chip dies, wire-bonding dies, passive electronic components, etc.), and fewer or more bump structures 20. Additionally, the flipped submodule 12 and the top components 16 may be located in a different layout on the top side of the module substrate 14, while the bottom components 18 and the bump structures 20 may be located in a different layout on the bottom side of the module substrate 14. Furthermore, the RF SIP module 10 may be a single-sided module instead of a double-sided module, so that the bottom components 18, the bump structures 20, and the bottom mold compound 24 may be omitted.

In detail, the module substrate 14 includes a laminate body 14B, which may be composed of prepreg (PPG) layers (not shown for clarity and simplicity), and multiple metal layers 26 alternating vertically with the PPG layers (not shown for clarity and simplicity). The multiple metal layers 26 have a top metal layer 26TL on a top surface of the laminate body 14B, a bottom metal layer 26BL on a bottom surface of the laminate body 14B, and multiple internal metal layers 261L embedded in the laminate body 14B. For the purpose of this illustration, the top metal layer 26TL includes top metal pads 26TP (for clarity and simplicity, only certain top metal pads are labeled with a reference number) to accommodate the top components 16 as well as the flipped submodule 12. Each top metal pad 26TP may have a same or different size with an appropriate shape, such as a circle, square, etc. In some embodiments, a certain top metal pad 26TP may be used as a ground plane. The top metal layer 26TL may also include other top metal features (not shown for clarity and simplicity), such as top routing lines to connect between the top metal pads 26TP and/or to provide at least a portion of a certain passive component (e.g., a coil, a capacitor, a resistor, a transformer, etc.). Similarly, the bottom metal layer 26BL includes bottom metal pads 26BP (for clarity and simplicity, only certain bottom metal pads are labeled with a reference number) to accommodate the bottom components 18 and the bump structures 20. Each bottom metal pad 26BP may have a same or different size with an appropriate shape, such as a circle, square, etc. The bottom metal layer 26BL may also include other bottom metal features (not shown for clarity and simplicity), such as bottom routing lines to connect between the bottom metal pads 26BP and/or to provide at least a portion of a certain passive component (e.g., a coil, a capacitor, a resistor, a transformer, etc.). The multiple metal layers 26 are electrically connected through vias VV (for clarity and simplicity, only certain vias are labeled) and are designed to establish electrical and thermal connections (with vias VV) among the flipped submodule 12, the top components 16, the bottom components 18, and the bump structures 20. Additionally, these metal layers 26 may also be configured to provide passive components (e.g., coils, capacitors, resistors, transformers, etc.).

For a non-limiting example, the first top component 16-1 is a flip-chip die with solder balls 28 and implemented as a gallium arsenide (GaAs) power amplifier (PA), the second top component 16-2 is a surface mounted device (SMD) that may be configured to provide a coil and used for impedance match before an antenna switch (not shown) or for impedance match of the PA/low noise amplifier (LNA), and the third top component 16-3 is also a flip-chip die with solder balls 30 and implemented as a wafer-level packaged (WLP) bulk acoustic wave (BAW) filter (for clarity and simplicity, only one solder ball of the first top component 16-1 and one solder ball of the third top component 16-3 are labeled with reference numbers). Each top component 16 is attached to the top side of the module substrate 14 on one or more corresponding top metal pads 26TP. In different applications, there might be fewer or more top components 16 attached to the top side of the module substrate 14 via corresponding top metal pads 26TP, respectively. The top components 16 may be other types of electrical components, such as wire-bonding dies, flip-chip dies with die copper pillars, and/or passive components, and are used to achieve different functionalities. The top components 16 might be mounted to the top metal pads 26TP with or without an adhesive material (e.g., the second top component, SMD, 16-2 is mounted to the corresponding top metal pads 26TP with an adhesive material 32, while the first and third top components, flip-chip dies with solder balls, 16-1 and 16-3 are attached to the corresponding top metal pads 26TP directly).

In addition, the first bottom component 18-1 is a flip-chip die which includes solder balls 34 and is implemented as a silicon-on-insulator (SOI) low noise amplifier (LNA), and the second bottom component 18-2 is also a flip-chip die with solder balls 36 and is implemented as an SOI switch (for clarity and simplicity, only one solder ball of the first bottom component 18-1 and one solder ball of the second bottom component 18-2 are labeled with reference numbers). Each bottom component 18 is attached to the bottom side of the module substrate 14 on multiple corresponding bottom metal pads 26BP. The bump structures 20, which protrude from the bottom side of the module substrate 14 and surround the bottom components 18, are either solder balls (the RF SIP module 10 is packaging with the double-sided molded ball grid array technology) or copper posts (the RF SIP module 10 is packaging with the double-sided molded land grid array technology). Each bump structure 20 is formed on a corresponding bottom metal pad 26BP on the bottom side of the module substrate 14. In different applications, there might be fewer or more bottom components 18 attached to the bottom side of the module substrate 14 via corresponding bottom metal pads 26BP. The bottom components 18 may be other types of electrical components, such as wire-bonding dies, flip-chip dies with die copper pillars, and/or passive components, and are used to achieve different functionalities. The bottom components 18 and the bump structures 20 might be mounted to the bottom metal pads 26BP with or without an adhesive material (not shown).

Referring to the flipped submodule 12, it is designed to provide efficient heat dissipation paths and improved electrical performance for one or more electronic components within the flipped submodule 12. The flipped submodule 12 includes a submodule substrate 38, one or more submodule components 40, submodule interconnections 42, and a submodule mold compound 44. Herein, the submodule substrate 38 includes a laminate body 38B composed of PPG layers (not shown) and multiple metal layers 48 alternating vertically with the PPG layers. To achieve good electrical performance and a low-profile for the flipped submodule 12, the submodule substrate 38 may only include 3-5 metal layers 48. For the purpose of this illustration, the submodule substrate 38 includes a first metal layer 48FL on a first surface of the laminate body 38B, a second metal layer 48SL on a second surface of the laminate body 38B, and an internal metal layer 48IL vertically between the first metal layer 48FL and the second metal layer 48SL and inside the laminate body 38B. The first surface of the laminate body 38B faces the top side of the module substrate 14 and is vertically opposite to the second surface of the laminate body 38B. The internal metal layer 48IL is electrically connected to both the first metal layer 48FL and the second metal layer 48SL through vias (not shown for clarity and simplicity). Each of the metal layers 48 may include one or more metal features (e.g., metal pads, metal traces, etc.), which is designed to provide at least a portion of one passive component (e.g., a coil, a capacitor, a resistor, a transformer, etc.), or multiple passive components and/or to achieve electrical and thermal connections among these passive components. Additionally, the first metal layer 48FL is also configured to accommodate the submodule components 40 as well as the submodule interconnections 42. In different applications, the submodule substrate 38 may include two or more internal metal layers 48IL. Each of the metal layers 48 may incorporate a variety of metal features, which may vary in shape, size, and/or layouts.

The one or more submodule components 40 are attached to a first side of the submodule substrate 38, which faces the top side of the module substrate 14. For the purpose of this illustration, there are two submodule components 40 (e.g., a first submodule component 40-1 and a second submodule component 40-2), each of which is a flip-chip die with solder balls 50 (for clarity and simplicity, only one solder ball is labeled with a reference number). Each submodule component 40 has a same height and may have a same or different horizontal size. Each submodule component 40 is attached to the first side of the submodule substrate 38 by connecting each solder ball 50 to a corresponding metal feature of the first metal layer 48FL. A backside of each submodule component 40 (herein and hereafter, a backside of one flip-chip die refers to a surface away from an active region of the flip-chip die and opposite the die solder balls/die copper pillars) is thermally connected to the module substrate 14 through a thermal interface material 51. Herein, the thermal interface material 51 is directly positioned between the backside of each submodule component 40 and a corresponding top metal pad 26TP (e.g., the ground plane) on the top side of the module substrate 14. The thermal interface material 51 is a material that may have a thermal conductivity larger than 3 W/mK and is desired to be electrically insulative to avoid degradation of RF performance of the submodule components 40, such as MX-4, Kryonaut Extreme, etc. The thermal interface material 51 may have a thickness typically between 20 μm and 30 μm (e.g., about 20 μm).

The submodule mold compound 44 is vertically between the first side of the submodule substrate 38 and the top side of the module substrate 14, surrounds each submodule component 40, and underfills the submodule components 40 if the submodule components 40 are flip-chip dies (i.e., fills gaps among the solder balls 50 of the submodule components 40). The submodule mold compound 44 may be an organic epoxy resin system or the like, and may be formed of a same material as or a different material from the top mold compound 22. Each submodule interconnection 42 is in contact with a corresponding metal feature of the first metal layer 48FL and extends through the submodule mold compound 44 from the first side of the submodule substrate 38 towards a corresponding top metal pad 26TP of the module substrate 14. In this illustration, the submodule interconnections 42 are located at a periphery of the first side of the submodule substrate 38 and surround the submodule components 40. Each submodule interconnection 42 is electrically and thermally conductive and may be a copper pillar, a solder ball, or a bond-wire. Herein, each submodule component 40 is connected to one or more submodule interconnections 42 through one or more metal layers 48 and the vias of the submodule substrate 38, and is further connected to one or more of the top components 16, one or more of the bottom components 18, and one or more of the bump structures 20 through the metal layers 26 and the vias of the module substrate 14.

In different applications, the flipped submodule 12 may include fewer or more submodule components 40 attached to the first side of the submodule substrate 38, and may include more submodule interconnections 42 extending from the first side of the submodule substrate 24 to the top side of the module substrate 14. The submodule components 40 may achieve different functionalities (e.g., PAs, filters, switches, etc.). In addition, the flipped submodule 12 may include other electronic components (e.g., SMDs, wire-bonding dies, etc.), which are attached to the first side of the submodule substrate 38 but not connected to the module substrate 14 through the thermal interface material 51. These other electronic components are thinner than the submodule components 40 and fully covered by the submodule mold compound 44 (not shown). The horizontal layout of the submodule components 40 and the submodule interconnections 42 might also be different. For a non-limiting example, one or more of the submodule interconnections 42 may be located at an interior area of the first side of the submodule substrate 38, extend vertically through the submodule mold compound 44 and between the submodule components 40 (not shown).

With the configuration of the flipped submodule 12 as described above, heat generated in the submodule components 40 can be dissipated to the module substrate 14 in two thermal paths (considering only metal thermal conductance as a dominant heat dissipation mechanism). A first thermal path P1 is from the solder balls 50 of each of the submodule components 40, through the metal layers 48 (and possibly vias) of the submodule substrate 38 and the submodule interconnections 42, through the metal layers 26 and the vias W in the module substrate 14, through the bump structures 20, and towards an external assembly (e.g., a printed circuit board). A second thermal path P2 is from the backside of each submodule component 40, through the thermal interface material 51, through the metal layers 26 and the vias W in the module substrate 14, through the bump structures 20, and towards the external assembly. Compared to a flip-chip die directly attached to the module substrate 14 (similar to the attachment of the first top component 16-1), which only has one thermal path—from solder balls 28, through the metal layers 26 and the vias W in the module substrate 14, through the bump structures 20, and towards the external assembly—the submodule components 40 within the flipped submodule 12 have an additional thermal path P2 through the backside, which increases thermal contact areas between the submodule components 40 and the top the metal layer 26TL of the module substrate 14. Additionally, since the backside of each flip-chip die 40 has a much larger surface area than its solder balls 50, this additional thermal path P2 through the backside can efficiently dissipate the heat generated in the flip-chip die 40 to the module substrate 14, and thereby significantly reduce a thermal resistance of each submodule component 40.

In the case where the RF SIP module 10 is a RF front-end (FE) module, the submodule components 40 within the flipped submodule 12 may be acoustic filters (e.g., BAW filters, surface acoustic wave—SAW—filters, etc.). These acoustic filters 40 have different frequency bands and are connected by a multiplexing (MUX) network before an antenna switch (not shown) to form a multiplexer (e.g., a duplexer, a quadplexer, a hexaplexer, etc.). As such, the acoustic filters 40 in each filter group (like duplexer, quadplexer, hexaplexer, etc.) can be individually selected by the antenna switch to operate. Typically, the MUX network includes one or more coils and optional capacitors. In some applications, the MUX network may be implemented by the metal layers 26 of the module substrate 14 as well as one or more SMDs mounted on the module substrate 14 (e.g., the second top component, SMD, 16-2). Herein, the metal layers 26 provides integrated module passive components (e.g. coils and optional capacitors) for impedance matching before the antenna switch as well as routing lines that electrically connect the module components, the one or more SMDs, and the acoustic filters 40. In some applications, the MUX network may be implemented completely or partially by the metal layers 48 of the submodule substrate 38. Herein, the metal layers 48 provide integrated submodule passive components (e.g. coils and optional capacitors) for impedance matching before the antenna switch as well as routing lines that electrically connect the integrated submodule passive components and the acoustic filters 40. Regardless of whether the metal layers 48 within the submodule substrate 38 are used for the MUX network or not, the metal layers 48 are always configured to provide one or more corresponding ground coils (e.g., 1 to 3 coils connected to ground) for each acoustic filter 40. Exemplary implementations of discrete coils by using the laminate technology can be found in U.S. Provisional Patent Application No. 63/774,819, CUSTOM RF INDUCTORS FOR RF MODULES, which is incorporated herein by reference.

When the MUX network is implemented within the submodule substrate 38 instead of within the module substrate 14, electromagnetic (EM) coupling between the MUX network and the other components (e.g., the second bottom component 18-2 implemented as the SOI switch) can be reduced due to increased separation from each other. Additionally, the number of passive components integrated in the module substrate 14 can be reduced, which in turn reduces the number of metal layers 26 in the module substrate 14 (as well as the connection complexity of the module substrate 14).

In addition, the enhanced thermal management of the flipped submodule 12 can lower the operating temperature of each acoustic filter 40 and improve its frequency characteristic, thereby improving overall module performance over temperature (e.g., preventing output power drop and reducing current consumption in the RF SIP module 10). In the case where the RF SIP module 10 is a RF front-end (FE) module, the transmitter-receiver isolation can be improved due to better centering of the upper band edge of the acoustic filters 40. Furthermore, due to the increased thermal contact areas, there might be an opportunity to reduce the size of each acoustic filter 40 in a transmitter (TX), which can still dissipate the heat efficiently. In different applications, the submodule substrate 38 of the flipped submodule 12 may realize other functionalities, such as output matching baluns or transformers for power amplifiers, input/output impedance matching for RF components, and/or couplers.

In some embodiments, the RF SIP module 10 may be shielded by a module shielding structure 52 to be a shielded RF SIP module 10S, so as to reduce or eliminate electromagnetic interference (EMI) and radiation. In this illustration, the module shielding structure 52 covers a top surface of the RF SIP module 10 (i.e., a top surface of the top mold compound 22) and a combined side surface of the top mold compound 22 and the module substrate 14. Alternatively, the module shielding structure 52 may cover the top surface of the RF SIP module 10 and a side surface of the RF SIP module 10 (i.e. a combined side surface of the top mold compound 22, the module substrate 14, and the bottom mold compound 24). In either scenario, the top mold compound 22 fully encapsulates the flipped submodule 12, such that a certain portion of the top mold compound 22, which is positioned vertically above the flipped submodule 12, is configured to prevent the module shielding structure 52 from being electrically coupled to the submodule substrate 38. Additionally, the module shielding structure 52 never covers a bottom side of the RF SIP module 10, and each bump structure 20 is exposed through the bottom mold compound 24 for next level assembly. The module shielding structure 52 may include multiple shielding layers, each of which may be formed of copper, aluminum, silver, gold, stainless steel, nickel, or other conductive materials.

Further, it has been recognized that eddy RF currents, which come from radiative components within a module, may exist within internal surfaces of a shielding structure. When those eddy RF currents interact with other components, the performance of the overall module is negatively impacted. Herein, to individually isolate one or more radiative components within the RF SIP module 10, one or more internal shielding structures 54 are introduced. Each internal shielding structure 54 is connected to a corresponding top metal pad 26TP, extends vertically through the top mold compound 22, and is in contact with the module shielding structure 52. Both the internal shielding structures 54 and the module shielding structure 52 are electrically connected to the ground plane. The one or more internal shielding structures 54 may be implemented by multiple discreate bond-wires or one or more continuous metal plates (not shown). Exemplary implementations of the internal shielding structures 54 can be found in U.S. Pat. No. 10,410,972, INTEGRATED MODULE WITH ELECTROMAGNETIC SHIELDING, which is incorporated herein by reference. In this illustration, when the first top component 16-1 is an RF PA, the internal shielding structure 54 is configured to isolate the first top component 16-1 from other top components as well as the flipped submodule 12.

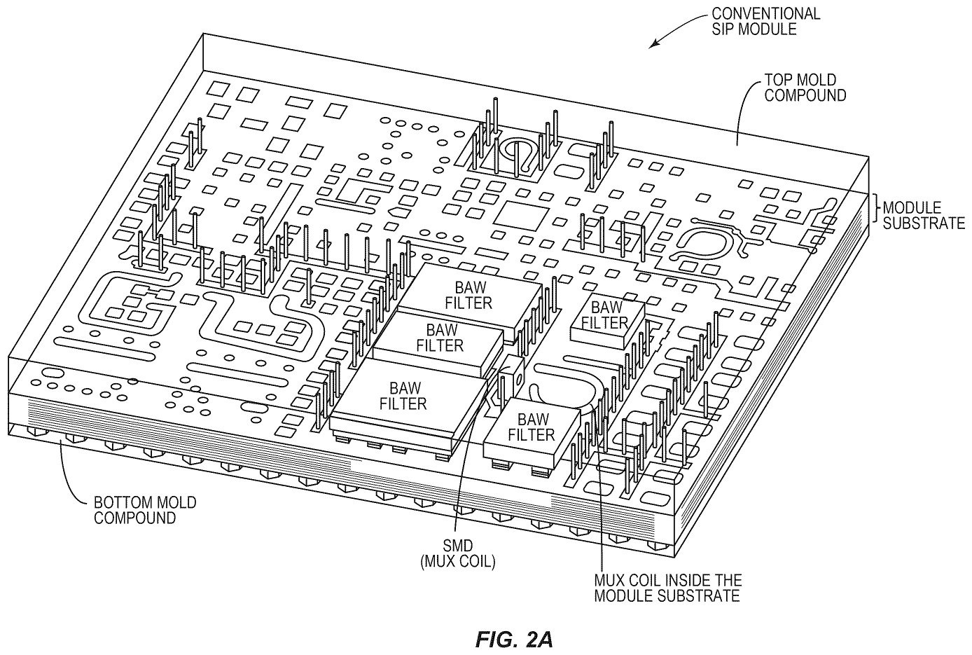

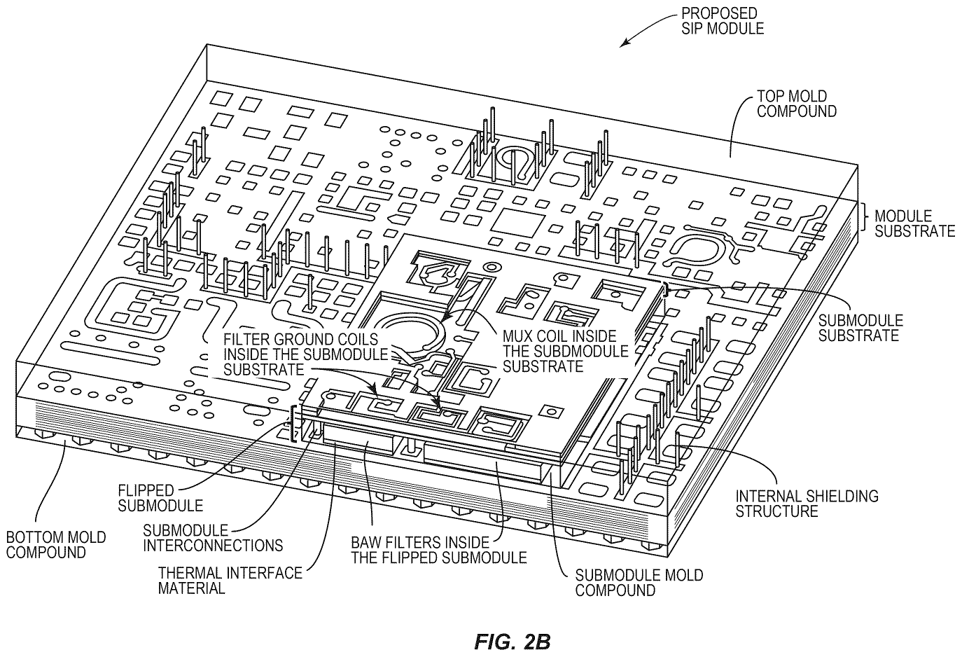

FIGS. 2A and 2B provide three-dimensional (3D) plots for different RF SIP modules. FIG. 2A illustrates a 3D plot of a conventional RF SIP module, which does not include any flipped submodule as described above. The conventional RF SIP module shown in FIG. 2A includes flip-chip BAW filters and corresponding coils implemented in a SMD or embedded in a module substrate of the conventional RF SIP module. FIG. 2B illustrates a plot of a proposed RF SIP module that includes one flipped submodule (e.g., the flipped submodule 12) as described above. The proposed RF SIP module shown in FIG. 2B features the flipped submodule that includes at least one flip-chip BAW filter (e.g., the submodule flip-chip BAW filters 40) and corresponding coils (e.g., one or more coils for the MUX network, and/or ground coils associated with the submodule flip-chip BAW filters 40) embedded in a submodule substrate of the flipped submodule.

For a thermal performance comparison, linear thermal simulations with 1 W bulk silicon injection (BSI) excitation are applied to one flip-chip BAW filter of the conventional RF SIP module and to one flip-chip BAW filter within the flipped submodule of the proposed RF SIP module. The proposed flipped submodule configuration results in a significant reduction in temperature distribution across the flip-chip BAW filter compared to that of the flip-chip BAW filter within the conventional RF SIP module. Simulation parameters of the BAW filters are summarized in Table 1 below. Benefiting from the proposed flipped submodule configuration, the maximum temperature for one BAW filter decreases from 65.1 °C to 35.5 °C, and the thermal resistance for one BAW filter decreases from 46.7 K/W to 38.6 K/W. Therefore, the reliability of the BAW filter in the proposed flipped submodule will also be enhanced.

TABLE 1

| | Rth, | Tmax, | |
|---|---|---|---|
| Variant | K/W | deg. C | Comment |
| 1 | 46.7 | 65.1 | BSI, BAW filter in the conventional RF SIP |
| | | | module |
| 2 | 38.6 | 35.5 | BSI, BAW filter in the proposed RF SIP |
| | | | module including a flipped submodule |
| | | | w/thermal interface material |

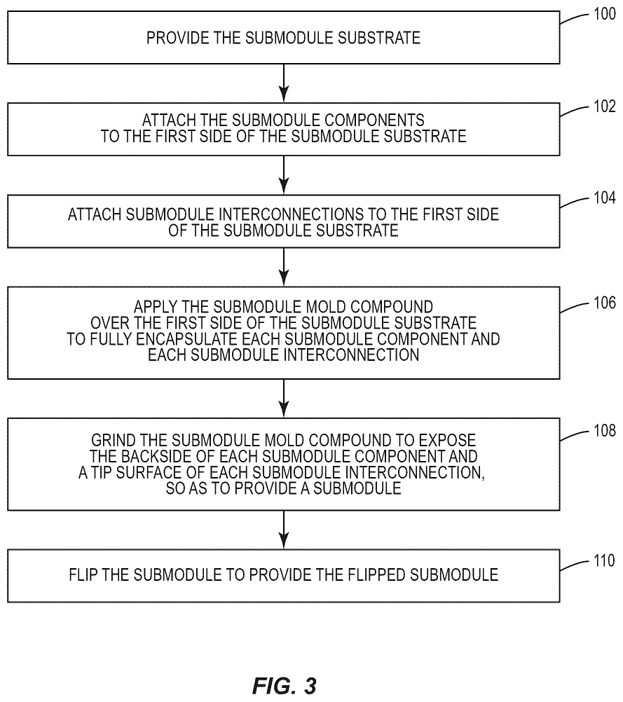

FIG. 3 provides a flow diagram that illustrates an exemplary process for manufacturing the flipped submodule 12 according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those provided in FIG. 3.

Initially, the submodule substrate 38 is provided (step 100). Herein, the submodule substrate 38, as described above, includes the laminate body 38B composed of PPG layers and the metal layers 48 alternating vertically with the PPG layers. For good electrical performance and a low-profile, the submodule substrate 38 may only include 3-5 metal layers 48. The first metal layer 48FL is on the first surface of the laminate body 38B, the second metal layer 48SL is on the second surface of the laminate body 38B, and the one or more internal metal layers 48IL are vertically between the first metal layer 48FL and the second metal layer 48SL and inside the laminate body 38B. In this processing step, the first surface of the laminate body 38B is a top surface of the laminate body 38B, while the second surface of the laminate body 38B is a bottom surface of the laminate body 38B. The first metal layer 48FL, the one or more internal metal layers 48IL, and the second metal layer 48SL are electrically connected to each other through vias. Each of the metal layers 48 may include one or more metal features (e.g., metal pads, metal traces, etc.), which may vary in shape, size, and/or layouts. The metal layers 48 are designed to provide one or more passive components (e.g., coils, capacitors, resistors, transformers, etc.), and to accommodate submodule components and submodule interconnections formed in subsequent steps, and to provide electrical routing connections among the passive components, the submodule components, and the submodule interconnections.

Next, the submodule components 40 are attached to the first side of the submodule substrate 38 (step 102), where the first side of the submodule substrate 38 is a top side of the submodule substrate 38 in this step. When the submodule components 40 are flip-chip dies with the solder balls 50 as described above, the attachment is achieved by connecting each solder ball 50 to a corresponding metal feature of the first metal layer 48FL on the first surface of the laminate body 38B. The backside of each flip-chip die 40 is away from the submodule substrate 38. Each submodule component 40 may be any suitable RF component, such as a BAW filter, a SAW filter, a PA, and/or a passive component. Additionally, the submodule interconnections 42 are also attached to the corresponding metal features of the first metal layer 48FL at the first side of the submodule substrate 38 (step 104). Each submodule interconnection 42 is electrically and thermally conductive and might be a copper pillar, a solder ball, or a bond-wire as described above.

After assembling the submodule components 40 and the submodule interconnections 42, a submodule mold compound 44 is then applied over the first side of the submodule substrate 38 to fully encapsulate each submodule component 40 and each submodule interconnection 42 (step 106). The submodule mold compound 44 also underfills the submodule components 40 if the submodule components 40 are flip-chip dies (i.e., fills gaps among the solder balls 50 of the submodule components 40). The submodule mold compound 44 may be applied by various procedures, such as compression molding, sheet molding, overmolding, transfer molding, dam fill encapsulation, and screen print encapsulation. A curing process (not shown) is then used to harden the submodule mold compound 44 depending on which material is used to form the submodule mold compound 44.

A grinding step is then applied to thin down the submodule mold compound 44 until the backside of each submodule component 40 and a tip surface of each submodule interconnection 42 are exposed, so as to provide a submodule (step 108). Before the grinding step, the submodule components 40 may or may not have a same height, whereas after the grinding step, the backside of each submodule component 40 and the tip surface of each submodule interconnection 42 are coplanar.

Before being assembled into the RF SIP module 10, the submodule is flipped up-side down to provide the flipped submodule 12 (step 110). Herein, the submodule substrate 38 is at the top of the flipped submodule 12, while the backside of each submodule component 40 and the tip surface of each submodule interconnection 42 are exposed through the submodule mold compound 44 and at the bottom of the flipped submodule 12. Additionally, the first surface of the laminate body 38B of the submodule substrate 38 is flipped as the bottom surface of the laminate body 38B, and the first metal layer 48FL becomes a bottom metal layer of the submodule substrate 38. Similarly, the second surface of the laminate body 38B of the submodule substrate 38 is flipped as the top surface of the laminate body 38B, and the second metal layer 48SL becomes a top metal layer of the submodule substrate 38. The submodule substrate 38 is flipped so that the first side becomes the bottom side of the submodule substrate 38.

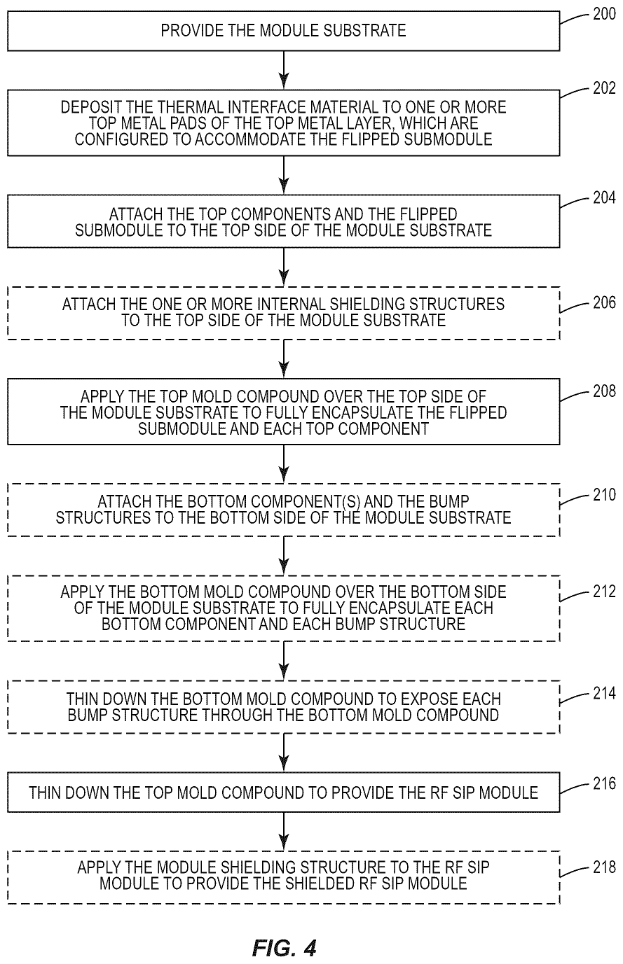

FIG. 4 provides a flow diagram that illustrates an exemplary process for manufacturing the RF SIP module 10 using the flipped submodule 12 according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those provided in FIG. 4.

Firstly, the module substrate 14 is provided (step 200). Herein, the module substrate 14 includes the laminate body 14B composed of PPG layers and the multiple metal layers 26 alternating vertically with the PPG layers. The multiple metal layers 26 include the top metal layer 26TL on the top surface of the laminate body 14B, the bottom metal layer 26BL on the bottom surface of the laminate body 14B, and multiple internal metal layers 261L embedded in the laminate body 14B. The thermal interface material 51 is then directly deposited on one or more top metal pads 26TP of the top metal layer 26TL (step 202), which are configured to accommodate the flipped submodule 12 and may serve as a ground plane. The thermal interface material 51 may have a thermal conductivity larger than 3 W/mK and is desired to be electrically insulative to avoid degradation of RF performance of the submodule components 40.

Next, the flipped submodule 12 and the top components 16 are attached to the top side of the module substrate 14 (step 204). Herein, the flipped submodule 12 is mounted to the module substrate 14 by attaching the tip surface of each submodule interconnection 42 to a corresponding top metal pad 26TP and attaching the backside of each submodule component 40 to the one or more top metal pads 26TP covered by the thermal interface material 51. In particular, the thermal interface material 51 on the one or more top metal pads 26TP is in contact with the backside of each submodule component 40, while the tip surface of each submodule interconnects 42 is electrically connected to a corresponding top metal pad 26TP with or without an adhesive material. Similarly, the top components 16 are mounted to the module substrate 14 by attaching to corresponding top metal pads 26TP of the top metal layer 26TL with or without an adhesive material (e.g., the second top component, SMD, 16-2 is mounted to the corresponding top metal pad 26TP with the adhesive material 32, while the first and third top components, flip-chip dies with solder balls, 16-1 and 16-3 are directly attached to the corresponding top metal pads 26TP). The top components 16 may be any suitable types of electrical components, such as flip-chip dies with die solder balls, flip-chip dies with die copper pillars, wire-bonding dies, SMDs, etc., and are used to achieve different functionalities, such as PAs, switches, filters, passive components, etc.

To reduce internal EMI and radiation within the final product, the internal shielding structures 54 may be applied in combination with the module shielding structure 52 formed in a subsequent step. Each internal shielding structure 54 is attached to a corresponding top metal pad 26TP (step 206) and has a greater height than the flipped submodule 12 and any top component 16. The internal shielding structures 54 may surround any radiative top component 16 (such as a PA), so as to individually isolate such radiative top component 16. The internal shielding structures 54 may be implemented by multiple discreate bond-wires or one or more continuous metal plates.

Next, the top mold compound 22 is applied over the top side of the module substrate 14 to fully encapsulate the flipped submodule 12 and each top component 16 (step 208). The top mold compound 22 may also underfill any top component 16 if the top component 16 is a flip-chip die (i.e., fills gaps underneath any top component 16). The top mold compound 22 may be an organic epoxy resin system or the like, and may be applied by various procedures, such as compression molding, sheet molding, overmolding, transfer molding, dam fill encapsulation, and screen print encapsulation. A curing process (not shown) is then used to harden the top mold compound 22 depending on which material is used to form the top mold compound 22.

If the final RF SIP module 10 features a double-sided structure, the one or more bottom components 18 and the bump structures 20 are attached to the bottom side of the module substrate 14 (step 210). The bottom components 18 are mounted to the module substrate 14 by attaching to corresponding bottom metal pads 26BP of the bottom metal layer 26BL with or without an adhesive material. The top components 16 may be any suitable types of electrical components, such as flip-chip dies with die solder balls, flip-chip dies with die copper pillars, wire-bonding dies, SMDs, etc., and are used to achieve different functionalities, such as LNAs, switches, filters, passive components, etc. Similarly, each bump structure 20 is attached to a corresponding bottom metal pad 26BP of the bottom metal layer 26BL with or without an adhesive material. Each bump structure 20 may be a solder ball or a copper post, and typically has a greater height than the bottom components 18. The bottom components 18, the bump structures 20, the top components 16, and the flipped submodule 12 are electrically connected through the metal layers 26 and the vias (not shown) of the module substrate 14.

The bottom mold compound 24 is then applied over the bottom side of the module substrate 14 to fully encapsulate the bottom components 18 and the bump structures 20 (step 212, if the final multi-level SIP module 10 is a single sided module, this step will be omitted). The bottom mold compound 24 also underfills any bottom component 18 if the bottom component 18 is a flip-chip die (i.e., fills gaps underneath any bottom component 18). The bottom mold compound 24 may be an organic epoxy resin system or the like, and may be formed of a same material as or a different material from the top mold compound 22. The bottom mold compound 24 may be applied by various procedures, such as compression molding, sheet molding, overmolding, transfer molding, dam fill encapsulation, and screen print encapsulation. A curing process (not shown) is then used to harden the bottom mold compound 24 depending on which material is used to form the bottom mold compound 24.

The bottom mold compound 24 is then thinned down to expose each bump structure 20 through the bottom mold compound 24 (step 214). The thinning step may be done with a grinding process. If the bottom component 18 is a silicon-based flip-chip die, the bottom component 18 may also be ground at the same time as the bottom mold compound 24 until each bump structure 20 is exposed through the bottom mold compound 24. After the thinning step, the side surface of each bottom component 18 and the side surface of each bump structure 20 are still encapsulated by the bottom mold compound 24. In some applications, the bottom component 18 may be shorter than the bump structures 20, such that, after the thinning step, the bottom component 18 is still fully encapsulated by the bottom mold compound 24. In some applications, the bottom component 18 may be no shorter than the bump structures 20, such that, after the thinning step, the backside of the bottom component 18 is exposed through the bottom mold compound 24, and is coplanar with the bottom mold compound 24 and an end surface of each bump structure 20. Alternatively, this thinning step is omitted, if the end surface of each bump structure 20 is always exposed during the molding process of the bottom mold compound 24.

Next, the top mold compound 22 on the top side of the module substrate 14 is thinned down to provide the RF SIP module 10 (step 216). If the internal shielding structures 54 are not presented, the top mold compound 22 is thinned down to meet the final module thickness target without exposing any of the flipped substrate 12 and the top components 16. If the internal shielding structures 54 are presented, the top mold compound 22 is thinned down until a tip surface of each internal shielding structure 54 is exposed through the top mold compound 22. Since the flipped substrate 12 and each top component 16 are shorter than the internal shielding structures 54, after this thinning step, the flipped substrate 12 and each top component 16 are still completely encapsulated by the top mold compound 22. The thinning step may be done with a grinding process.

Lastly and optionally, the module shielding structure 52 may be applied to the RF SIP module 10 to provide the shielded RF SIP module 10S (step 218). The module shielding structure 52 directly and completely covers the top surface of the top mold compound 22 and at least covers the combined side surface of the top mold compound 22 and the module substrate 14, while the bottom side of the RF SIP module 10 is always exposed. If the internal shielding structures 54 are presented, the module shielding structure 52 is required, and the module shielding structure 52 is in contact with each internal shielding structure 54 at the top surface of the top mold compound 22. As such, any radiative component surrounded by the internal shielding structures 54 can be individually shielded inside the shielded RF SIP module 10S.

According to aspects disclosed herein, RF SIP modules and methods for manufacturing the RF SIP modules to achieve high electronic density, low-profile, and small footprint may be provided in or integrated into any processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

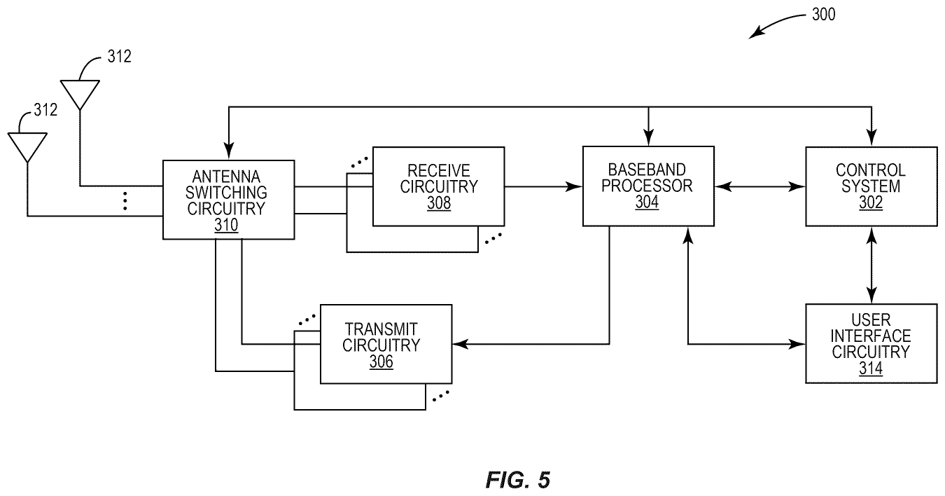

With reference to FIG. 5, the concepts described above may be implemented in various types of communication devices 300, such as those listed in the previous paragraph. The communication device 300 will generally include a control system 302, a baseband processor 304, transmit circuitry 306, receive circuitry 308, antenna switching circuitry 310, multiple antennas 312, and user interface circuitry 314. Herein, at least one or any combination of the control system 302, the baseband processor 304, the transmit circuitry 306, and the receive circuitry 308 may be implemented in the RF SIP module 10/10S as shown in FIG. 1, and described above.

In a non-limiting example, the control system 302 can be a field-programmable gate array (FPGA) or an application-specific integrated circuit (ASIC), as an example. In this regard, the control system 302 can include at least a microprocessor(s), an embedded memory circuit(s), and a communication bus interface(s). The receive circuitry 308 receives radio frequency signals via the antennas 312 and through the antenna switching circuitry 310 from one or more base stations. A low noise amplifier and a filter of the receive circuitry 308 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 304 processes the digitized received signal to extract the information or data bits conveyed in the received signal. This processing typically comprises demodulation, decoding, and error correction operations, as will be discussed in greater detail below. The baseband processor 304 is generally implemented in one or more digital signal processors (DSPs) and ASICs.

For transmission, the baseband processor 304 receives digitized data, which may represent voice, data, or control information, from the control system 302, which it encodes for transmission. The encoded data is output to the transmit circuitry 306, where a digital-to-analog converter(s) (DAC) converts the digitally encoded data into an analog signal and a modulator modulates the analog signal onto a carrier signal that is at a desired transmit frequency or frequencies. A PA will amplify the modulated carrier signal to a level appropriate for transmission and deliver the modulated carrier signal to the antennas 312 through the antenna switching circuitry 310. The multiple antennas 312 and the replicated transmit and receive circuitries 306, 308 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A radio frequency (RF) system-in-package (SIP) module comprising:
a module substrate;
a flipped submodule attached to a top side of the module substrate including a submodule substrate, at least one submodule component, and a plurality of submodule interconnects, wherein:
the at least one submodule component is a flip-chip die attached to a first side of the submodule substrate that faces the top side of the module substrate;
a backside of the at least one submodule component is thermally connected to the top side of the module substrate via a thermal interface material, which allows heat generated by the at least one submodule component to dissipate from the backside of the at least one submodule component towards the module substrate;
the plurality of submodule interconnects extends from the first side of the submodule substrate towards the top side of the module substrate and is configured to provide electrical and thermal connections between the submodule substrate and the module substrate; and
the submodule substrate includes a plurality of metal layers, which is configured to provide at least one passive component and achieve electrical and thermal connections among the at least one passive component, the at least one submodule component, and the plurality of submodule interconnects; and
at least one top component attached to the top side of the module substrate.

2. The RF SIP module of claim 1, wherein the thermal interface material has a thermal conductivity larger than 3 W/mK and a thickness between 20 μm and 30 μm.

3. The RF SIP module of claim 1, wherein the submodule substrate includes 3 to 5 metal layers.

4. The RF SIP module of claim 1, wherein the at least one submodule component comprises one or more acoustic filters, and the at least one passive component comprises one or more corresponding ground coils.

5. The RF SIP module of claim 1, wherein:
the at least one submodule component comprises two or more acoustic filters; and
the plurality of metal layers within the submodule substrate is configured to provide one or more corresponding ground coils for each of the two or more acoustic filters.

6. The RF SIP module of claim 5, wherein the plurality of metal layers within the submodule substrate is further configured to provide a multiplexing network connected to the two or more acoustic filters, thereby forming a multiplexer, such that the two or more acoustic filters of the multiplexer are capable of being individually selected by an antenna switch to operate.

7. The RF SIP module of claim 5, wherein the two or more acoustic filters are bulk acoustic wave (BAW) filters or surface acoustic wave (SAW) filters.

8. The RF SIP module of claim 1, wherein the at least one passive component comprises at least one of a coil, a capacitor, a resistor, a transformer.

9. The RF SIP module of claim 1, wherein each of the plurality of submodule interconnects is a copper pillar, a solder ball, or a wire-bond.

10. The RF SIP module of claim 1, wherein:
the module substrate includes a top metal layer formed on the top side of the module substrate, wherein the top metal layer includes a plurality of top metal features;
the thermal interface material is directly and vertically positioned between the backside of the at least one submodule component and a corresponding one of the plurality of top metal features on the top side of the module substrate; and
each of the plurality of submodule interconnects is electrically connected to another corresponding one of the plurality of top metal features on the top side of the module substrate.

11. The RF SIP module of claim 10, wherein the flipped submodule further includes a submodule mold compound, which is formed vertically between the first side of the submodule substrate and the top side of the module substrate, surrounds the at least one submodule component and each of the plurality of submodule interconnects, and underfills the at least one submodule component.

12. The RF SIP module of claim 11 further comprising a top mold compound, wherein the top mold compound is formed on the top side of the module substrate to fully encapsulate the at least one top component and the flipped submodule.

13. The RF SIP module of claim 12, wherein the top mold compound and the submodule mold compound are formed from different materials.

14. The RF SIP module of claim 12 further comprising a module shielding structure, wherein the module shielding structure directly and continuously covers a top surface of the top mold compound and a combined side surface of the top mold compound and the module substrate.

15. The RF SIP module of claim 14 further comprising one or more internal shielding structures, each of which is connected to a corresponding one of the plurality of top metal features on the top side of the module substrate, extends vertically through the top mold compound, and is in contact with the module shielding structure.

16. The RF SIP module of claim 1 further comprising at least one bottom component and a plurality of bump structures, wherein the at least one bottom component and the plurality of bump structures are attached to a bottom side of the module substrate, which is opposite from the top side of the module substrate.

17. The RF SIP module of claim 16 further comprising a bottom mold compound, wherein:
the bottom mold compound surrounds each of the plurality of bump structures without covering an end surface of each of the plurality of bump structures; and
the bottom mold compound at least surrounds the at least one bottom component, wherein the at least one bottom component does not vertically extend beyond the bottom mold compound.

18. A communication device comprising:
a control system;
a baseband processor;
receive circuitry; and
transmit circuitry, wherein at least one or any combination of the control system, the baseband processer, the transmit circuitry, and the receive circuitry is implemented in an RF SIP module, which at least includes a module substrate, a flipped submodule, and at least one top component, wherein:
the at least one top component and the flipped submodule, which includes a submodule substrate, at least one submodule component, and a plurality of submodule interconnects, are attached to a top side of the module substrate;
the at least one submodule component is a flip-chip die attached to a first side of the submodule substrate that faces the top side of the module substrate;
a backside of the at least one submodule component is thermally connected to the module substrate via a thermal interface material, which allows heat generated by the at least one submodule component to dissipate from the backside of the at least one submodule component towards the module substrate;
the plurality of submodule interconnects extends from the first side of the submodule substrate towards the top side of the module substrate and is configured to provide electrical and thermal connections between the submodule substrate and the module substrate; and
the submodule substrate includes a plurality of metal layers, which is configured to provide at least one passive component and achieve electrical and thermal connections among the at least one passive component, the at least one submodule component, and the plurality of submodule interconnects.

19. A method of manufacturing an RF SIP module comprising:
forming a flipped submodule, which includes a submodule substrate, at least one submodule component, and a plurality of submodule interconnects, wherein:
the at least one submodule component is a flip-chip die attached to a first side of the submodule substrate, such that a backside of the at least one submodule component is away from the first side of the submodule substrate;
the plurality of submodule interconnects are formed on the first side of the submodule substrate; and
the submodule substrate includes a plurality of metal layers, which is configured to provide at least one passive component and achieve electrical and thermal connections among the at least one passive component, the at least one submodule component, and the plurality of submodule interconnects;
depositing a thermal interface material on a top side of a module substrate;
attaching at least one top component and the flipped submodule to the top side of the module substrate, wherein:
the backside of the at least one submodule component is thermally connected to the top side of the module substrate via the thermal interface material, which allows heat generated by the at least one submodule component to dissipate from the backside of the at least one submodule component towards the module substrate; and
each of the plurality of submodule interconnects extends from the first side of the submodule substrate towards the top side of the module substrate and is configured to provide electrical and thermal connections between the submodule substrate and the module substrate.

20. The method of claim 19, wherein the thermal interface material has a thermal conductivity larger than 3 W/mK and a thickness between 20 μm and 30 μm.
